(19) United States
(12) Patent Application Publication
(10) Pub. No.: US 2025/0015780 A1
(43) Pub. Date: Jan. 9, 2025

(54) TRAVELING-WAVE SURFACE ACOUSTIC WAVE TRANSDUCER AND INTERCONVERTING AN ELECTRICAL SIGNAL AND A SURFACE ACOUSTIC WAVES

(71) Applicant: Government of the United States of America, as represented by the Secretary of Commerce, Gaithersburg, MD (US)

(72) Inventors: Adam Nykoruk McCaughan, Denver, CO (US); Ryan Anthony DeCrescent, Boulder, CO (US); Kevin Lawrence Silverman, Denver, CO (US)

(21) Appl. No.: 18/763,229

(22) Filed: Jul. 3, 2024

Related U.S. Application Data
(60) Provisional application No. 63/524,755, filed on Jul. 3, 2023.

(51) Int. Cl. H03H 9/145; H03H 3/08

(52) U.S. Cl. CPC H03H 9/14502; H03H 3/08

(57) ABSTRACT

A traveling-wave surface acoustic wave transducer includes a superconducting wire arranged in a meander configuration to create a meander of superconducting wire, and a piezoelectric crystal that has an induced electrical field in response to piezoelectric action from surface acoustic waves and/or from an input electrical signal traveling through the meander of superconducting wire.

### RELATED APPLICATIONS

This application claims the benefit of U.S. Provisional Patent Application Ser. No. 63/524,755 (filed Jul. 3, 2023), which is herein incorporated by reference in its entirety.

### FEDERALLY-SPONSORED RESEARCH AND DEVELOPMENT

This invention was made with United States Government support from the National Institute of Standards and Technology (NIST), an agency of the United States Department of Commerce. The Government has certain rights in this invention.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF INVENTION

The present invention relates generally to surface acoustic wave transducers, and more particularly to surface acoustic wave transducers utilizing superconducting nanowires.

### BACKGROUND

Conventional technology for electro-acoustic transduction (where electrical energy is converted to acoustic/mechanical energy) involves interdigitated transducers (IDT) that have a fixed, non-broadband response function that does not allow for the conversion of broadband electrical signals into acoustic signals.

### SUMMARY OF INVENTION

Problematically, conventional IDTs radiate in multiple directions at once, e.g., to the left and the right, which can be non-ideal. Additionally, conventional IDTs are generally not tunable, and one cannot turn their electro-acoustic coupling on and off. Traveling-wave surface acoustic wave transducer described herein overcomes these technical limitations and can be used in RF signal processing and quantum information.

In a typical traveling-wave configuration, transduction is usually accomplished by matching the phase velocities of two systems, for instance by placing an electrical transmission line on top of a photonic waveguide and ensuring that velocities of the optical and electrical modes match. However, this matching is extremely difficult in the case of electrical-to-acoustic transduction, as the phase velocities differ by a factor of 105. One can overcome this mismatch by meandering the wires perpendicularly so that the electrical phase velocity along the SAW axis is reduced, but with a typical conductor this would require extreme dimensions e.g. 150-nm-wide wires meandered 15 mm.

However, superconducting nanowires can have electrical propagation velocities on the order of 0.01c, reducing the phase-velocity mismatch to approximately 103. This enables the creation of devices with practical dimensions, e.g. 150-nm-wide wires meandered 150 μm. Moreover, these superconducting nanowire transmission lines have near-zero loss at the SAW frequencies of relevance, and so are an ideal transduction platform for quantum transduction processes.

An exemplary traveling-wave surface acoustic wave transducer may interconvert an electrical signal and surface acoustic waves in a broadband, directional, low-loss, and tunable manner.

According to one aspect of the invention, a traveling-wave surface acoustic wave transducer includes a superconducting wire arranged in a meander configuration to create a meander of superconducting wire; and a piezoelectric crystal that has an induced electrical field in response to piezoelectric action from surface acoustic waves and/or from an input electrical signal traveling through the meander of superconducting wire.

Optionally, the traveling-wave surface acoustic wave transducer also includes a microwave transmission line that includes a ground plane, the piezoelectric crystal, and the meander of superconducting wire.

Optionally, the traveling-wave surface acoustic wave transducer also includes a dielectric layer between the ground plane and the piezoelectric crystal.

Optionally, the traveling-wave surface acoustic wave transducer also includes a first terminal and a second terminal that connect to opposite ends of the meander of superconducting wire and provide input/output of electrical signal therethrough.

Optionally, the superconducting wire has high kinetic inductance.

Optionally, the piezoelectric crystal is GaAs.

Optionally, the ground plane is a normal metal or superconducting metal and adds capacitance to the system, thereby lowering electrical transmission velocity.

Optionally, the traveling-wave surface acoustic wave transducer also includes a pair of parallel surface acoustic wave mirrors spaced around the meander of superconducting wire forming a mirror chamber therebetween and configured to store information in the form of a reflecting surface acoustic wave therein.

According to another aspect of the invention, a process for interconverting an electrical signal and a surface acoustic waveform includes impinging a surface acoustic wave onto a meander of superconducting wire; converting the surface acoustic waves coherently into a transduced electrical signal due to velocity matching condition between a net electrical velocity in a direction and surface acoustic wave velocity in the same direction; and sending the transduced electrical signal out to a terminal.

Optionally, the process proceeds in the opposite order.

According to another aspect of the invention, a process for making exemplary traveling-wave surface acoustic wave transducers includes starting with a piezoelectric crystal; patterning on the piezoelectric crystal a meander of superconducting wire with dimensions such that an effective electrical velocity in a direction along a piezoelectric axis matches a surface acoustic wave velocity in the same direction; connecting a first terminal to a second terminal via the meander of superconducting wire; depositing on top, a dielectric layer to insulate the wire from a ground plane; and depositing on top of the dielectric layer the ground plane, thereby forming a microwave transmission line.

Optionally, the piezoelectric crystal is gallium arsenide.

Optionally, the piezoelectric crystal is a LiNbO wafer.

The foregoing and other features of the invention are hereinafter described in greater detail with reference to the accompanying drawings.

### BRIEF DESCRIPTION OF THE DRAWINGS

FIG. 1 shows, according to some embodiments, a traveling-wave surface acoustic wave transducer.

FIG. 2 shows, according to some embodiments, a traveling-wave surface acoustic wave transducer.

FIG. 3 shows, according to some embodiments, a traveling-wave surface acoustic wave transducer.

FIG. 4 shows, according to some embodiments, a traveling-wave surface acoustic wave transducer.

FIG. 5 shows, according to some embodiments, a traveling-wave electro-acoustic transduction process and transducers that include meandered transmission lines, wherein sine wave voltages are input to the left terminal of the input transducer. The SAW waves travel across a short delay gap and are transduced back into the electrical domain at the receiving transducer, where they are emitted from the right terminal.

FIG. 6 shows, according to some embodiments, a traveling-wave electro-acoustic memory device.

### DETAILED DESCRIPTION

Exemplary traveling-wave surface acoustic wave (SAW) transducers (TWST) utilize superconducting wires as slow-wave transmission lines as a means to convert electrical signals to and from surface acoustic wave signals. In a typical traveling-wave transducer such as an electro-optic traveling wave transducer, the transduction process is accomplished by matching the phase velocities of two systems, for instance by placing an electrical transmission line on top of a photonic waveguide and ensuring that velocities of the optical and electrical modes match. When this velocity-matching condition is met, it allows the energy of one system (e.g. electrical) to interact with the other system (e.g. optical) for a long duration, as they co-propagate spatially near each other. However, this matching is extremely difficult in the case of electrical-to-acoustic transduction, as the velocities of a typical microwave transmission line and a surface acoustic wave differ by a factor of 100,000. One can overcome this mismatch by meandering the wires perpendicularly so that the effective velocity of the electrical energy in the X-direction (where X is one of the piezoelectric axes of the piezoelectric crystal) is reduced. This is nominally possible to do with a typical conductor (e.g. not a superconductor), but would require extreme and unreasonable dimensions to realize—e.g. 150-nm-wide wires meandered 15 mm. However, superconducting nanowires can have propagation velocities on the order of 1% of the speed of light, reducing the phase-velocity mismatch to approximately a factor of 1,000. This enables the creation of devices with practical dimensions, e.g. 150-nm-wide wires meandered 150 μm.

By laying out superconducting nanowires in a meandered configuration, and placing a ground plane nearby, one can create this transducer. With a nearby ground plane, the superconducting wires, piezoelectric crystal, dielectric layer, and the ground form the necessary microwave transmission line with low propagation velocity.

When an electrical signal is input to the superconducting wires via a terminal, it propagates along the length of the wire at a minor percentage of the speed of light, e.g., about 0.5%-1% of the speed of light, and along the X-direction at a much lower speed—the same speed as the surface acoustic waves. As the electrical signal travels down the superconducting wires, it induces differing voltages on each section of the meandered wire. These differing voltages induce an electrical field in the nearby piezoelectric crystal, which in turn induces strain of the atomic lattice of the crystal due to the piezoelectric effect. This strain naturally co-propagates as waves along the surface of the crystal in the X-direction, forming the beginning of a surface acoustic wave. The result is as the electrical signal travels down the wire, it co-propagates with the strain of the surface acoustic wave, constructively interfering and converting more and more of the energy in the electrical signal to surface acoustic waves.

Conventional technology for electro-acoustic transduction (where electrical energy is converted to acoustic/mechanical energy) involves interdigitated transducers (IDT) that have a fixed, non-broadband response function that does not allow for the conversion of broadband electrical signals into acoustic signals. Problematically, most conventional IDTs radiate in multiple directions at once, e.g., to the left and the right, which can be non-ideal. Additionally, conventional IDTs are generally not tunable, and one cannot turn their electro-acoustic coupling on and off. Exemplary traveling-wave surface acoustic wave (SAW) transducers described herein overcome these technical limitations and can be used in RF signal processing and quantum information.

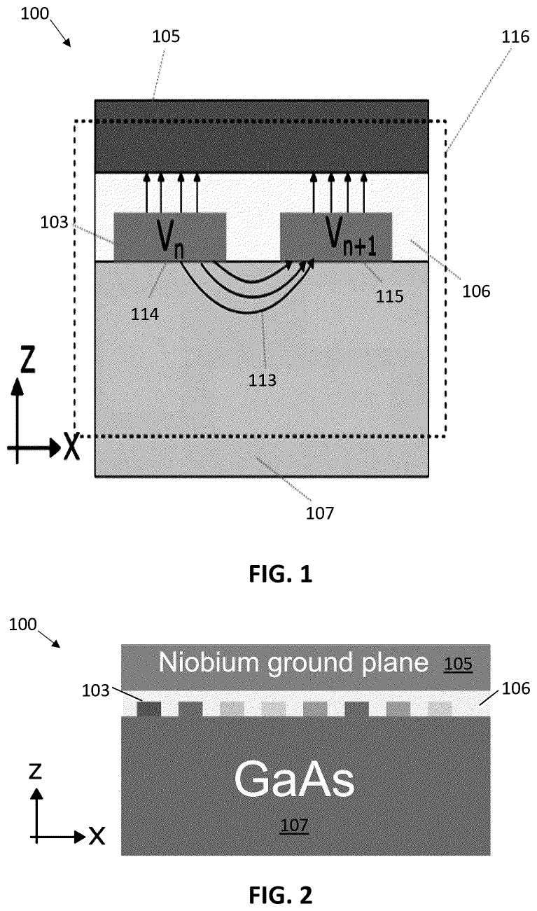

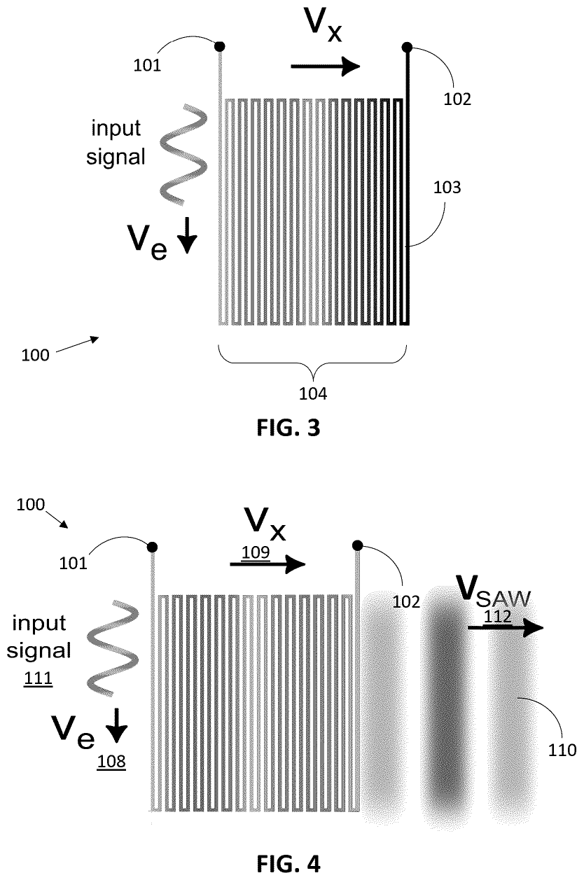

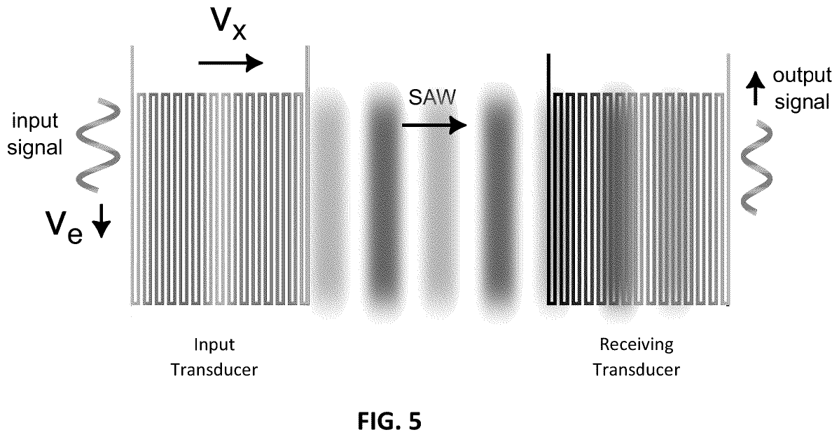

In an embodiment, with reference to FIG. 1, FIG. 2, FIG. 3, FIG. 4, and FIG. 5, traveling-wave surface acoustic wave transducer 100 includes: superconducting wires 103 arranged in a winding/meander configuration to create a meander of superconducting wires 104; piezoelectric crystal 107 that has an induced electrical field 113 in response to piezoelectric action from surface acoustic waves 110 and/or from input electrical signal 111; microwave transmission line 116 that includes: ground plane 105, piezoelectric crystal 107, superconducting wires 103, and optional dielectric layer 106; and terminal A 101 and terminal B 102 that connect to the meander of superconducting wires 104 and provide input/output of electrical signal 111.

Traveling-wave surface acoustic wave transducer 100 is a traveling-wave SAW transducer (TWST) that includes superconducting nanowires. In an embodiment, traveling-wave surface acoustic wave transducer 100 includes a GaAs substrate that interconverted broadband electrical signals to and from SAWs.

Optionally, a niobium ground plane adds capacitance to the system, lowering electrical transmission velocity further.

The superconducting-nanowires are slow-wave transmission lines that provided a phase-velocity matching condition between the electromagnetic and acoustic modes. As shown in FIG. 4, surface acoustic waves 110 match the electrical velocity 109 in the x-direction via a combination of slow electrical velocity Vₑ 108 along a wire direction, and the meandering path 104 of the wires. Although the electrical path length is long because of the meandering path 104, the electrical loss is low along the path because of the use of a superconductor. In other words, the superconducting material enables the meandering path practical because of high kinetic inductance—a feature of the material and dimensions of the device.

Traveling-wave surface acoustic wave transducer 100 has beneficial properties for classical and quantum transduction, including: broadband transmission and reception, near-zero electrical dissipation, intrinsic directionality, and tunable coupling either through an applied B-field, temperature, or by modifying the nanowire kinetic inductance by means of an injected current.

Traveling-wave surface acoustic wave transducer 100 can be made of various elements and components that are microfabricated. Elements of traveling-wave surface acoustic wave transducer 100 can be various sizes. Elements of traveling-wave surface acoustic wave transducer 100 can be made of a material that is physically or chemically resilient in an environment in which traveling-wave surface acoustic wave transducer 100 is disposed. Exemplary materials include a metal, ceramic, thermoplastic, glass, semiconductor, and the like. The elements of traveling-wave surface acoustic wave transducer 100 can be made of the same or different material and can be monolithic in a single physical body or can be separate members that are physically joined.

Terminal A 101 is one of two electrical terminals of the transducer. Terminal B 102 is a second of two electrical terminals of the transducer.

Superconducting wires 103 can be made from a superconducting material with high kinetic inductance, on which electrical energy can flow and eventually be transduced into surface acoustic waves 110. Meander of superconducting wires 104 includes superconducting wires 103 meandered up and down, e.g., mostly in the Y-direction, to reduce the electrical velocity in x-direction 109.

Ground plane 105 can be a layer of metal or set of electrodes that acts as an electrical reference plane which when combined with superconducting wires 103 to creates microwave transmission line 116.

Dielectric layer 106 can be a layer of dielectric material that is an insulator between superconducting wires 103 and ground plane 105.

Piezoelectric crystal 107 can be a material that exhibits piezoelectricity, providing coupling of electrical modes to acoustic modes via electric field 113.

Electrical velocity 108 along wire direction is a propagation velocity of the electrical signal 111, provided by the specific geometry and materials composing the microwave transmission line 116. Electrical velocity 109 in the x-direction is an effective propagation velocity of the electrical signal 111 in the x-direction and can be smaller than the electrical velocity along wire direction 108 by a factor determined by the geometry of the meander of superconducting wires 104, wherein electrical velocity 109 can be approximately matched to the surface acoustic wave velocity 117 for the transduction process to occur. Surface acoustic waves 110 are acoustic (mechanical) waves that propagate in the x-direction in the crystalline structure of piezoelectric crystal 107.

Electrical signal 111 is an input or output electrical waveform that includes one or more frequency components, wherein electrical signal 111 can be an input converted into surface acoustic waves 110 or can be the result of transduction of surface acoustic waves 110 into electrical output.

Surface acoustic wave velocity 112 is a propagation velocity of the surface acoustic waves 112 in the x-direction.

Electrical field 113 is an electrical field generated by the difference in electrical potential (voltage) of wires n 114 and wires (n+1). Some portion of the electrical field exists in the dielectric layer 106 and is not part of the transduction/conversion process, while the component in the piezoelectric crystal 107 is involved in the transduction/conversion process. Voltage 114 of wire n is an approximate/average electrical potential of wire n of the meander of superconducting wires 104 at time t, either induced by piezoelectric action of piezoelectric crystal 107 or generated directly by electrical signal 111. Voltage 15 of wire n is an approximate/average electrical potential of wire n+1 of the meander of superconducting wires 104 at time t, either induced by piezoelectric action of piezoelectric crystal 107 or generated directly by electrical signal 111. Microwave transmission line 116 can include superconducting wires 103 as the signal conductor, and ground plane 105 as the ground conductor, with the dielectric layer 106 or piezoelectric crystal 107 that has dielectric insulator between them, wherein microwave transmission line 116 can determine a characteristic electric velocity along wire direction 108.

The previous paragraphs describe the operation of the TWST as a converter of electrical energy to acoustic energy-it takes as input a broadband electrical signal, and coherently converts some or all of the energy to surface acoustic waves. The TWST can also be used in the reverse direction, as a receiver-coherently converting some or all of an incoming surface acoustic wave signal to an output electrical signal which is emitted through one of the terminals.

The resulting TWST has many beneficial properties. Since the microwave transmission line is constructed from superconductors, it will have near-zero loss at the SAW frequencies of relevance (e.g. <50 GHZ). Additionally, it is unidirectional—for example in the X-direction of the emission of the surface acoustic wave will match the X-direction of the electrical signal. It also is broadband, allowing the transmission and receiving of arbitrary electrical and acoustic waveforms over a large frequency range. Lastly, it is tunable—the transduction process can be enabled or disabled by tuning a variety of parameters, including temperature, magnetic field, or DC current bias.

Exemplary traveling-wave surface acoustic wave transducers can be made in various ways. It should be appreciated that exemplary traveling-wave surface acoustic wave transducers include a number of optical, electrical, or mechanical components, wherein such components can be interconnected and placed in communication (e.g., optical communication, electrical communication, mechanical communication, and the like) by physical, chemical, optical, or free-space interconnects. The components can be disposed on mounts that can be disposed on a bulkhead for alignment or physical compartmentalization. As a result, exemplary traveling-wave surface acoustic wave transducers can be disposed in a terrestrial environment or space environment. Elements of exemplary traveling-wave surface acoustic wave transducers can be formed from silicon, silicon nitride, and the like although other suitable materials, such ceramic, glass, or metal can be used.

The process for making exemplary traveling-wave surface acoustic wave transducers can include: starting with a piezoelectric crystal 107 of some form, e.g., a gallium arsenide or LiNbO wafer; patterning on it a meander of superconducting wires 104, with dimensions such that the effective electrical velocity of the in the x-direction 108 (along a piezoelectric axis) matches the surface acoustic wave velocity 112; connecting Terminal A 101 and Terminal B 102 to either end of the meander of superconducting wires 104, and potentially other terminals along the length of the superconducting wire 103; depositing on top a dielectric layer 106 to insulate the wires from the ground plane 105; and depositing on top of the dielectric layer 106 the ground plane 105 as the last step in forming a microwave transmission line 116.

The process for making exemplary traveling-wave surface acoustic wave transducers can include: starting with a piezoelectric crystal 107 of some form, e.g., a gallium arsenide or LiNbO wafer; patterning on it a meander of superconducting wires 103, with dimensions such that the effective electrical velocity of the in the x-direction 108 (along a piezoelectric axis) matches the surface acoustic wave velocity 112; connecting Terminal A 101 and Terminal B 102 to either end of the meander of superconducting wires 104, and potentially other terminals along the length of the superconducting wire 103 and depositing the ground plane 105 nearby or adjacent to the wires such that they form a microwave transmission line 116.

Exemplary traveling-wave surface acoustic wave transducers have numerous advantageous and unexpected benefits and uses. In an embodiment, a process for interconverting an electrical signal and a surface acoustic waves includes: inputting an electrical signal 111 into Terminal A 101; propagating the electrical signal 111 along the path of the meander of superconducting wires 104 with electrical velocity along wire direction 108 and electrical velocity in x-direction 109; converting the electrical signal 111 coherently into surface acoustic waves 110 due to the velocity matching condition between electrical velocity in x-direction 109 and surface acoustic wave velocity 112; and sending any remaining components of the electrical signal 111 that were not converted into surface acoustic waves 110 out to terminal B 102. Optionally, the process can include reversing Terminal A/B in the first and last steps, i.e., proceeding in the opposite direction.

In an embodiment, a process for interconverting an electrical signal and a surface acoustic waveform includes: impinging a surface acoustic wave 112 onto the meander of superconducting wires 104; converting the surface acoustic waves 112 coherently into electrical signal 111 due to the velocity matching condition between electrical velocity in x-direction 109 and surface acoustic wave velocity 112; and sending the transduced electrical signal 111 out to terminal A 101. Optionally, the process can include reversing in the first and last steps, i.e., proceeding in the opposite direction.

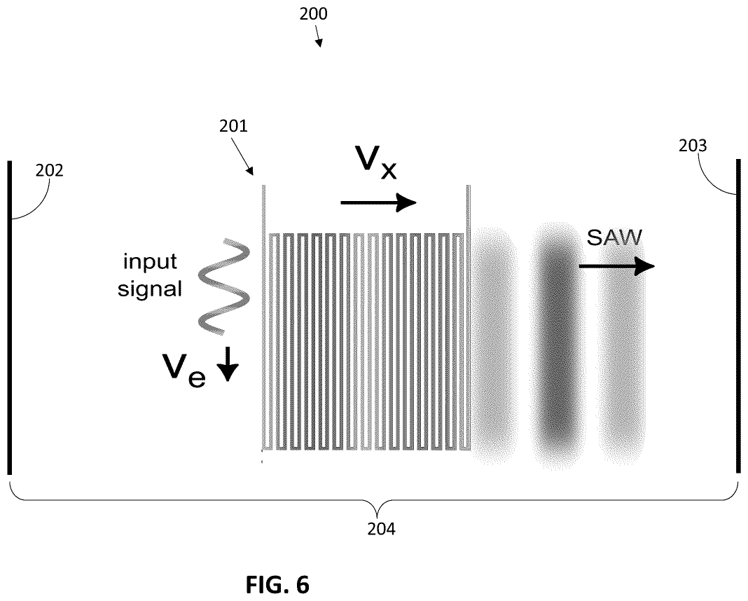

In an embodiment, and with respect to FIG. 6, a surface acoustic wave memory device 200 includes a surface acoustic wave transducer 201 as described with respect to any previous embodiment, sandwiched between a pair of parallel surface acoustic wave mirrors 202, 203 forming a mirror chamber 204 therebetween. When an electrical signal is received by the transducer 201, the signal is transduced into a SAW that may bounce between the mirrors for an amount of time while the transducer 201 is disabled (e.g., by tuning a variety of parameters, including temperature, magnetic field, or DC current bias) so as not to re-convert the SAW signal into an electrical signal while the SAW is reflected within the mirror chamber 204. When the information in the SAW is to be retrieved, the transducer 201 may be re-enabled and the SAW signal transduced into an electrical signal as described in previous embodiments.

In an embodiment, again with respect to FIG. 6, a frequency band may be swept through by surface acoustic wave transducer 201 to characterize the reflecting frequency of a SAW mirror 202. The signal frequency returned by the mirror 202 to the transducer 201 is the characteristic frequency of the mirror 202. While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. A traveling-wave surface acoustic wave transducer comprises:
a superconducting wire arranged in a meander configuration to create a meander of superconducting wire; and
a piezoelectric crystal that has an induced electrical field in response to piezoelectric action from surface acoustic waves and/or from an input electrical signal traveling through the meander of superconducting wire.

2. The traveling-wave surface acoustic wave transducer of claim 1, further comprising:
a microwave transmission line that includes a ground plane, the piezoelectric crystal, and the meander of superconducting wire.

3. The traveling-wave surface acoustic wave transducer of claim 2, further comprising:
a dielectric layer between the ground plane and the piezoelectric crystal.

4. The traveling-wave surface acoustic wave transducer of claim 1, further comprising:
a first terminal and a second terminal that connect to opposite ends of the meander of superconducting wire and provide input/output of electrical signal therethrough.

5. The traveling-wave surface acoustic wave transducer of claim 1, wherein the superconducting wire has high kinetic inductance.

6. The traveling-wave surface acoustic wave transducer of claim 1, wherein the piezoelectric crystal is GaAs.

7. The traveling-wave surface acoustic wave transducer of claim 2, wherein the ground plane is niobium and adds capacitance to the system, thereby lowering electrical transmission velocity.

8. The traveling-wave surface acoustic wave transducer of claim 4, further comprising a pair of parallel surface acoustic wave mirrors spaced around the meander of superconducting wire forming a mirror chamber therebetween and configured to store information in the form of a reflecting surface acoustic wave therein.

9. A process for interconverting an electrical signal and a surface acoustic waveform comprises:
impinging a surface acoustic wave onto a meander of superconducting wire;
converting the surface acoustic waves coherently into a transduced electrical signal due to velocity matching condition between a net electrical velocity in a direction and surface acoustic wave velocity in the same direction; and
sending the transduced electrical signal out to a terminal.

10. The process of claim 9, proceeding in an opposite order.

11. A process for making exemplary traveling-wave surface acoustic wave transducers, comprising:
starting with a piezoelectric crystal;
patterning on the piezoelectric crystal a meander of superconducting wire with dimensions such that an effective electrical velocity in a direction along a piezoelectric axis matches a surface acoustic wave velocity in the same direction;
connecting a first terminal to a second terminal via the meander of superconducting wire;
depositing on top, a dielectric layer to insulate the wire from a ground plane; and
depositing on top of the dielectric layer the ground plane, thereby forming a microwave transmission line.

12. The process of claim 11, wherein the piezoelectric crystal is gallium arsenide.

13. The process of claim 11, wherein the piezoelectric crystal is a LiNbO wafer.
